(19) United States
(12) Patent Application Publication
(10) Pub. No.: US 2007/0034937 A1
(43) Pub. Date: Feb. 15, 2007

(54) Semiconductor device and a method of manufacturing the same

(75) Inventor: Akihiko Sato, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/492,803

(22) Filed: Jul. 26, 2006

(30) Foreign Application Priority Data
Aug. 11, 2005 (JP) 2005-232977

(51) Int. Cl. H01L 29/788; H01L 21/82

(52) U.S. Cl. 257/315; 438/211; 257/390; 438/128; 257/E29.129

(57) ABSTRACT

A method of manufacturing a semiconductor device comprises forming a side wall spacer on side walls of an auxiliary gate in such a way that a CVD method using dichlorosilane as a staring material is carried out for deposition of a so-called high temperature oxide film (HTO film) at a high temperature of approximately 800° C. After the film formation, the film is post-annealed at temperatures higher than the film-forming temperature. In this way, the resulting side wall spacer becomes more dense than a silicon oxide film constituting part of a cap insulating film. Moreover, processing (double etching) of a control gate and a floating gate is performed by anisotropic dry etching and wet etching. Thus, the shape failure of the floating gate can be prevented, thereby preventing decrease in reliability and production yield.

### CROSS-REFERENCE TO RELATED APPLICATION

The present application claims priority from Japanese patent application No. 2005-232977 filed on Aug. 11, 2005, the content of which is hereby incorporated by reference into this application.

### BACKGROUND OF THE INVENTION

This invention relates to a semiconductor device and a method of manufacturing the same. More particularly, the invention relates to a technique effective for application to a nonvolatile semiconductor memory device wherein a memory cell is constituted of a floating gate electrode, a control gate electrode and an auxiliary gate electrode and also to its manufacturing method.

For an electrically rewriteable, nonvolatile memory, there is known a flash memory which is provided with a floating gate electrode for charge storage (hereinafter referred to simply as floating gate) and a control gate electrode (hereinafter referred to simply as control gate). One of flash memories of this type known in the art includes an AG (assist gate)-AND flash memory wherein an auxiliary gate electrode (hereinafter referred simply as auxiliary gate) is provided within a memory array thereby ensuring both a high writing speed and reduction in size of a memory cell.

The AG-AND memory flash is disclosed, for example, in Japanese Unexamined Patent Publication No. 2005-85903. In the memory array of the flash memory set forth in this publication, a plurality of auxiliary gates extending in one direction are arrayed in such a state that they are mutually adjacent. Above these auxiliary gates, a plurality of control gates, which extend along a direction intersecting at right angles with the direction of extension of the auxiliary gates, are arrayed as being mutually adjacent with each other, thereby constituting word lines. Moreover, a floating gate for charge storage is disposed within individual space regions of the plural auxiliary gates in such a state of being electrically isolated with the auxiliary gate and control gate.

As microfabrication proceeds, the AG-AND flash memory involves a lowering of a coupling ratio that is expressed by a ratio of an electrostatic capacitance between the floating gate and the control gate to a total electrostatic capacitance around the floating gate, making it difficult to operate the memory cell at high speed. To cope with this, the flash memory proposed in the above publication is so arranged that the height of the floating gate is higher than the height of the auxiliary gate, thereby contemplating to increase the coupling ratio.

In the AG-AND memory flash described in the publication, the floating gate higher than the auxiliary gate is formed briefly according to the following procedure.

Initially, a first polycrystalline silicon film for auxiliary gate is deposited on a silicon substrate, followed by further deposition of a cap insulating film on the first polycrystalline silicon film. The height of a floating gate is determined by a thickness of the auxiliary gate (the first polycrystalline silicon film) and a thickness of the cap insulating film, for which the cap insulating film is thickly formed. The cap insulating film is formed of a silicon nitride film serving as an etching stopper and a thick first silicon oxide film is deposited thereon.

Next, the cap insulating film and the first polycrystalline silicon film are patterned by dry etching using a mask of a photoresist film, thereby forming an auxiliary gate covered with the thick cap insulating film. According to the steps thus far described, a plurality of auxiliary gates extending in one direction are arrayed in a mutually adjacent manner in the memory array region of the silicon substrate.

Next, a side wall spacer is formed at side walls of the auxiliary gate and the cap insulating film. The side wall spacer is an insulating film electrically isolating the auxiliary gate and the floating gate from each other. For the formation of the side wall spacer, a second silicon oxide film is deposited on the silicon substrate, after which the second silicon oxide film is anisotropically etched to leave the film on the side walls of the auxiliary gate and the cap insulating film. The second silicon oxide film is deposited in a thickness not larger than a half of a space width of the auxiliary gate.

When the anisotropic etching is carried out, an etch-damaged layer including carbon caused by the etching is formed on the silicon substrate surface at the space region of the auxiliary gate. Hence, low damage dry etching is effected to remove the etch-damaged layer, and wet etching is further effected to clean the surface of the silicon substrate, followed by thermal treatment of the silicon substrate to form a thin silicon oxide film on the surface.

Next, a second polycrystalline silicon film for floating gate is deposited over the silicon substrate to fill the second polycrystalline silicon film in the space region of the auxiliary gate. Thereafter, the second polycrystalline silicon film is etched back on the surface thereof until the height of the surface becomes slightly lower than the surface height of the cap insulating film.

Next, part of the cap insulating film (first silicon oxide film) covering the auxiliary gate and the side wall spacer (second silicon oxide film) at the side walls are removed by dry etching. This etching is carried out by using the other part (silicon nitride film) of the cap insulating film as an etching stopper, and is stopped at the time when the surface of the silicon nitride film is exposed. By the steps thus far described, the second polycrystalline silicon film that is higher than the auxiliary gate is left in individual space regions of a plurality of auxiliary gates extending in one direction of the memory array region.

Next, a thin insulating film (ONO film) made of a silicon oxide film, a silicon nitride film and a silicon oxide film is formed over the silicon substrate, followed by deposition of a first conductor film for control gate on the ONO film. The first conductor film is constituted, for example, of a polycrystalline silicon film and a tungsten silicide film deposited thereon.

Thereafter, the first conductor film, and the underlying ONO film and the second polycrystalline silicon film are patterned by dry etching using a photoresist film as a mask, thereby forming a control gate (word line) made of the first conductor film. According to the steps thus far described, a plurality of control gates that extend in a direction intersecting at right angles with the extending direction of auxiliary gates are arrayed in a mutually adjacent manner in the memory array region of the silicon substrate. In addition, this dry etching allows the second polycrystalline silicon film extending in the same direction as the auxiliary gate to be isolated on a memory cell-to-memory cell basis, thereby forming a floating gate.

### SUMMARY OF THE INVENTION

The method of manufacturing a floating gate set forth in the above-described publication has the following problem. This is illustrated with reference to FIGS. 25 to 32.

For the formation of a floating gate, a p-type well 2 is initially formed on a semiconductor substrate 1 made of single crystal silicon and a gate oxide film 3 is subsequently formed on the surface of the p-type well 2 as is particularly shown in FIG. 25. Next, an n-type polycrystalline silicon film and a cap insulating film 35 are deposited on the gate oxide film 3, followed by pattering of the cap insulating film and the n-type polycrystalline silicon by dry etching using a photoresist film as a mask to form an auxiliary gate 34 made of the n-type polycrystalline silicon film. The cap insulating film 35 is constituted, for example, of a multilayered film of a silicon nitride film and a first silicon oxide film deposited thereon. Next, a second silicon oxide film 28a is deposited over the semiconductor substrate 1 by a CVD method. For the deposition of the second silicon oxide film 38a, there is used a CVD (chemical vapor deposition) method using a liquid source of TEOS (tetraethoxy silane) as a starting material. This is for the reasons: (1) the CVD method using TEOS as a starting material is relatively high in film-forming rate with the attendant advantage that the processing time can be shortened; and (2) such a method is unlikely to cause a loading effect that the film-forming speed changes depending on an exposed area ratio, and is suited for uniform film formation at a narrow space region between the adjacent auxiliary gates 34, 34.

Next, as shown in FIG. 26, the second silicon oxide film 38a is anisotropically etched to form a side wall spacer 28 at individual side walls of the auxiliary gate 34 and the cap insulating film 35. The side wall spacer 38 is formed under etching conditions of a relatively high pressure (of about 30 Pa).

When the anisotropic etching is carried out in a manner as described above, the p-type well 2 is etched on the surface thereof in the space region between the auxiliary gates 34, 34, so that the surface of the p-type well 2 is cleaned by wet etching, followed by thermal treatment of the substrate 1, to form a silicon oxide film 39 on the surface of the p-type well 2.

As shown in FIG. 27, an n-type polycrystalline silicon film 40n is deposited over the substrate 1 by use of a CVD method, after which the n-type polycrystalline silicon film 40n is etched back on the surface thereof to an extent that the surface is slightly lower than the surface of the cap insulating film 35. The n-type polycrystalline silicon film 40n is a conductor film that becomes a floating gate in a subsequent step.

Next, as shown in FIG. 28, part of the cap insulating film 35 (first silicon oxide film) is removed by dry etching. This dry etching is carried out using the remaining silicon nitride film of the cap insulating film 35 as an etching stopper. By the dry etching of the first silicon oxide film, the side wall spacer 38 above the upper surface of an exposed silicon nitride film is also removed, resulting in the upper surface of the silicon nitride film and the upper surface of the side wall spacer 28 being substantially at the same level. According to the foregoing steps, the n-type polycrystalline silicon film 40n that is higher than the auxiliary gate 34 and extends in the same direction as the auxiliary gate 34 is formed self-alignedly relative to the auxiliary gate 34 and the side wall spacer 38.

As shown in FIG. 29, after formation of an ONO film 41 over the substrate 1, an n-type polycrystalline silicon film 42n, a tungsten silicide film 42m and a silicon oxide film 43 are successively deposited on the ONO film 41. The ONO film 41 is constituted of trilayer insulating films (a silicon oxide film, silicon nitride film and silicon oxide film) deposited by a CVD method. The n-type polycrystalline silicon film 42n and the tungsten silicide film 42m become a conductor film serving as a control gate (word line) in a subsequent step.

Next, the silicon oxide film 43, tungsten silicide film 42m and n-type polycrystalline silicon film 42n are patterned to form a control gate 42 (word line) as shown in FIG. 30. Subsequently, the ONO film 41 and n-type polycrystalline silicon film 40n in a space region between the control gates 42, 42 are patterned to isolate the n-type polycrystalline silicon film 40n, which has extended in the same direction as the auxiliary gate 34 in a band shape, on a cell-to-cell basis, thereby forming a floating gate 40 self-alignedly relative to the control gate 42 (word line WL).

As stated hereinabove, for the formation, on the side wall of the auxiliary gate 34, of the side wall spacer 38 made of the second silicon oxide film 38a in the conventional manufacturing method, the second silicon oxide film 38a is deposited by a CVD method using starting TEOS. Moreover, when the second silicon oxide 38a is anisotropically etched to form the side wall spacer 38, etching conditions of a relatively high pressure (of about 30 Pa) are adopted.

Nevertheless, the second silicon oxide film (TEOS film) 38a deposited by the CVD method using starting TEOS is so low in denseness that the side wall spacer 38, subjected to the anisotropic etching and the subsequent wet etching, is liable to suffer shape variation. In addition, where the second silicon oxide film is subjected to anisotropic etching under relatively high pressure conditions, a so-called microloading effect takes place in the narrow space region between the auxiliary gates 34, 34, under which there occur a portion where etching proceeds and a portion where etching is unlikely to proceed, resulting in the likelihood of shape variation as well.

Thus, we revealed that the conventional manufacturing method has the problem that irregularities are apt to occur in the processed shape of the side wall spacer formed at the side walls of the auxiliary gate.

As stated hereinbefore, the floating gate of the AG-AND flash memory is formed self-alignedly relative to the auxiliary gate and the side wall spacer. Accordingly, where the side wall spacer that is an underlying layer of the floating gate is irregular in processed shape, the polycrystalline silicon film for floating gate, which is filled in the space region between the auxiliary gates, has a shape substantially in conformity with the processed shape of the side wall spacer. Eventually, in the step of forming the floating gate by etching of the polycrystalline silicon film, a portion of the polycrystalline silicon film that is hidden behind the side wall spacer is unlikely to undergo etching. In an extreme case, adjacent floating gates are not isolated from each other, thereby causing a short-circuiting failure.

If the portion of the polycrystalline silicon film that is hidden behind the side wall spacer is unlikely to etch, the planar shape of the polycrystalline silicon film becomes so deformed or warped that four corners that are all unlikely to etch are sharpened as if a horn protects from the corner, not going far enough to cause short-circuiting between adjacent floating gates (see FIG. 30). It is considered that if the floating gate is so shaped as set out above, a problem of a so-called “disturb phenomenon” is liable to rise, in which when writing operations of given memory cells are repeated, a threshold voltage of surrounding memory cells is unintentionally changed.

More particularly, as shown in FIG. 31, if a floating gate (FG₀) of a selected memory cell (MC₀) is sharpened at four corners thereof, an electric field is concentrated at the corners upon erasure, so that an electron in a high energy state is discharged against a silicon substrate. This electron discharged against the silicon substrate develops a secondary electron. The resulting electron again enters into the silicon oxide film on the substrate surface. The secondary electron that has entered into the silicon oxide film is kept away from the selected memory cell (MC₀) by the action of an electric field for erasure of the selected memory cell (MC₀). Especially, if opposingly adjacent selected memory cells (MC₁, MC₂) are in an erasing state where a threshold voltage is low, the electron is injected into the floating gates (FG₁, FG₂) of the adjacent memory cells (MC₁,, MC₂). In this way, when the floating gate (FG₀) of the selected memory cell (MC₀) is sharp at the four corners thereof, a disturb phenomenon wherein a threshold voltage of the adjacent memory cells (MC₁, MC₂) which would not be otherwise changed increases is caused by the influence of the secondary electron developed by means of an electron that is discharged upon erasure and has a high energy.

FIG. 32 is a graph showing a variation of a threshold voltage of adjacent memory cells (MC₁, MC₂) undergoing the disturb phenomenon mentioned above.

The word line selected on rewriting changes in each time. For one instance, there is the possibility that a certain word line is continuously selected to continue rewriting. Assuming such an extreme case, the threshold voltage of memory cells adjacent the selected memory cell having a floating gate whose four corners are sharp gradually increases owing to the disturb phenomenon and eventually exceeds a given range of voltage, thus leading to mal-writing of memory information. This is a disturb phenomenon against adjacent memory cells.

In the time to come, when miniaturization in memory size proceeds and a distance between memory cells becomes narrow, it is considered that such a problem as set out above becomes more conspicuous. Moreover, there is a problem in that it is difficult to judge a shape failure of the floating gate causing the disturb phenomenon in a pattern defect inspection step of a wafer process. Accordingly, in the course of the manufacturing procedure of an AG-AND flash memory, there is a demand of not causing a shape failure of the floating gate, i.e. not allowing the four corners to be sharp.

It is therefore an object of the invention to provide a technique for preventing reliability and production yield from lowering in a nonvolatile memory device such as an AG-AND flash memory.

Another object of the invention is to suppress a disturb phenomenon from occurring in a nonvolatile memory device.

The above and other objects and novel features of the invention will become apparent from the following description and the accompanying drawings.

A typical embodiment of the invention is summarized below.

The invention contemplates to provide a method of manufacturing a semiconductor device, comprising the steps of:

(a) forming a first conductor film on a main surface of a semiconductor substrate and subsequently forming, over the first conductor film, a cap insulating film having a thickness larger than the first conductor film;

(b) patterning the cap insulating film and the first conductor film to form a plurality of first conductor pieces which are covered with the cap insulating film over a top thereof and extend in a first direction at a given space therebetween;

(c) forming a high temperature oxide over a main surface of the semiconductor substrate by use of a CVD method using dichlorosilane as a starting material and anisotropically etching the high temperature oxide film to form a side wall spacer, made of the high temperature oxide film, on the respective side walls of a plurality of the first conductor pieces and the cap insulating film;

(d) cleaning the main surface of the semiconductor substrate and forming a silicon oxide film at space regions of the first conductor pieces by high temperature thermal oxidation treatment;

(e) forming a second conductor film over the main surface of the semiconductor substrate to fill the second conductor film in the respective space regions of the first conductor pieces covered with the cap insulating film;

(f) etching back the second conductor film by anisotropic etching to such an extent that the cap insulating film is exposed and the second conductor film is left on the space regions of the first conductor pieces;

(g) after the step (f), forming a first insulating film over the main surface of the semiconductor substrate and forming a third conductor film over the fist insulating film; and

(h) patterning the third conductor film, the first insulating film and the second conductor film to form a plurality of third conductor pieces which are each made of the third conductor film and extend in a second direction intersecting with the first direction at a given space therebetween, and forming a second conductor piece, made of the second conductor film, at a lower region of individual third conductor pieces.

According to the method embodying the invention, the following effects and advantages are obtainable.

In a nonvolatile memory device such as an AG-AND memory, lowering of reliability and of product yield can be prevented.

The disturb phenomenon can be suppressed in a nonvolatile flash memory.

### BRIEF DESCRIPTION OF THE DRAWINGS

FIG. 1 is a circuit diagram showing a memory array of an AND flash memory according to an embodiment of the invention;

FIG. 2 is a plan view briefly showing an essential part of the AND flash memory according to the embodiment of the invention;

FIG. 3 is a sectional view taken along line A-A of FIG. 2;

FIG. 4 is a sectional view showing an essential part of an AND flash memory in a manufacturing method of the memory according to the embodiment of the invention;

FIG. 5 is a sectional view showing an essential part of the AND flash memory at a step subsequent to FIG. 4;

FIG. 6 is a plan view showing an essential part of the AND flash memory at a step subsequent to FIG. 5;

FIG. 7 is a sectional view taken along line A-A of FIG. 6;

FIG. 8 is a sectional view showing an essential part of the AND flash memory at a step subsequent to FIG. 6;

FIG. 9 is a sectional view showing an essential part of the AND flash memory at a step subsequent to FIG. 8;

FIG. 10 is a plan view showing an essential part of the AND flash memory at a step subsequent to FIG. 9;

FIG. 11 is a sectional view taken along line A-A of FIG. 10;

FIG. 12 is a sectional view showing an essential part of the AND flash memory at a step subsequent to FIG. 10;

FIG. 13 is a sectional view showing an essential part of the AND flash memory at a step subsequent to FIG. 12;

FIG. 14 is a sectional view showing an essential part of the AND flash memory at a step subsequent to FIG. 13;

FIG. 15 is a sectional view showing an essential part of the AND flash memory at a step subsequent to FIG. 14;

FIG. 16 is a plan view showing an essential part of the AND flash memory at a step subsequent to FIG. 15;

FIG. 17 is a sectional view taken along line B-B of FIG. 16;

FIG. 18 is a plan view showing an essential part of the AND flash memory at a step subsequent to FIG. 16;

FIG. 19 is a sectional view taken along line B-B of FIG. 18;

FIG. 20 is a sectional view taken along line C-C of FIG. 18;

FIG. 21 is a schematic view showing a planar shape of a floating gate obtained by the manufacturing method according to the above embodiment;

FIG. 22 is a schematic view showing a planar shape of a floating gate obtained by a conventional manufacturing method;

FIG. 23 is a circuit diagram showing an erasure operation of the AND flash memory embodying the invention;

FIG. 24 is a circuit diagram showing a writing operation of the AND flash memory embodying the invention;

FIG. 25 is a sectional view of an essential part of an AND flash memory in a conventional manufacturing method of the memory;

FIG. 26 is a sectional view of an essential part of the AND flash memory at a step subsequent to FIG. 25;

FIG. 27 is a sectional view showing an essential part of the AND flash memory at a step subsequent to FIG. 26;

FIG. 28 is a sectional view showing an essential part of the AND flash memory at a step subsequent to FIG. 27;

FIG. 29 is a sectional view showing an essential part of the AND flash memory at a step subsequent to FIG. 28;

FIG. 30 is a plan view showing an essential part of the AND flash memory at a step subsequent to FIG. 29;

FIG. 31 is a plan view showing memory cells adjacent to a selected memory cell in the course of an erasure operation; and

FIG. 32 is a graph showing a variation in threshold voltage of an adjacent memory cells suffering a disturb phenomenon.

### DETAILED DESCRIPTION OF THE PREFERRED EMBODIMENTS

An embodiment of the invention is described with reference to the accompanying drawings. Like reference numerals indicate like members having the same function and are not repeatedly illustrated.

This embodiment is an application of the invention to an AG-AND flash memory having, for example, a capacity of 4 Gbits.

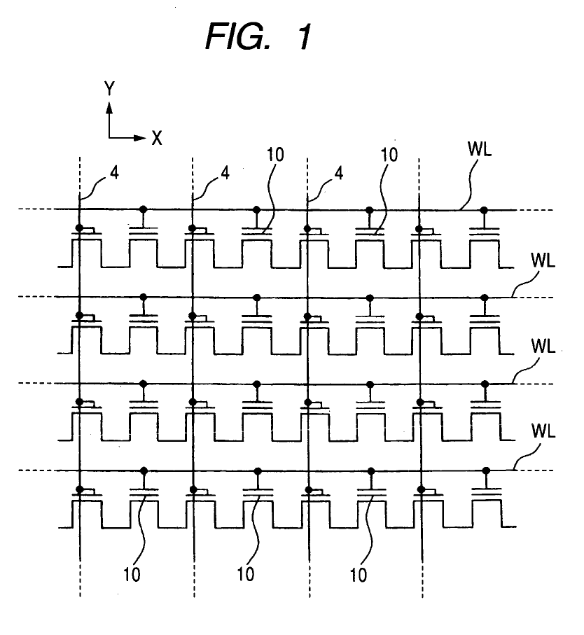

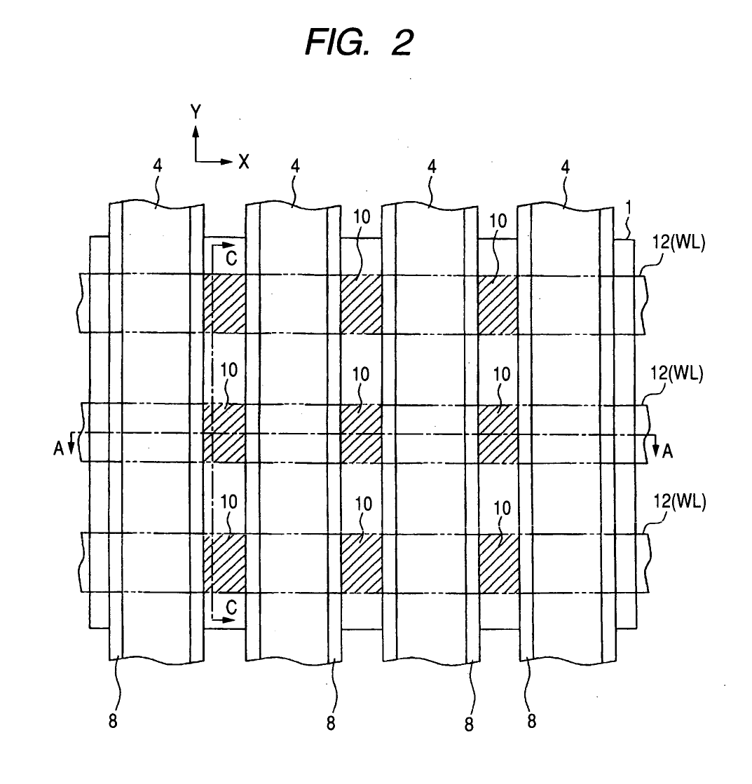

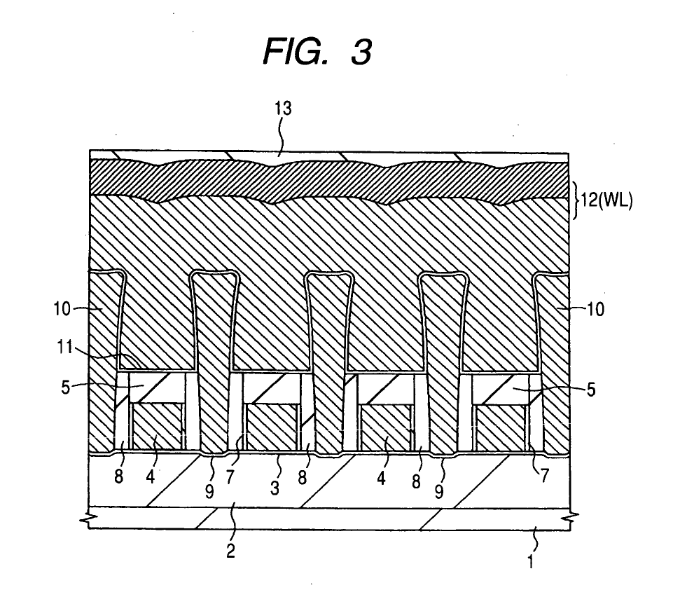

FIG. 1 is a circuit diagram of a memory array of an AND flash memory according to this embodiment, FIG. 2 is a plan view of an essential part briefly showing an arrangement of a memory array, and FIG. 3 is a sectional view, taken along line A-A.

The AND flash memory comprises a plurality of auxiliary gates 4 extending in a Y direction of a memory array, a plurality of control gates 12 extending in an X direction intersecting at right angles with the Y direction, and a floating gate 10 in the form of a film for charge storage which is disposed between mutually adjacent auxiliary gates 4,4 and is formed in a state insulated relative to the auxiliary gate 4 and the control gate 12. Although not limitative, the auxiliary gate 4 is provided, for example, as a unit including four gates, which are connected to a mutually common wiring (not shown), and, if necessary, is used to form a reversed layer serving for a writing operation and as a local bit line. Moe particularly, when a given voltage is applied to the auxiliary gate 4, an n-type reversed layer functioning as a source or drain of the memory cell is formed in the semiconductor substrate 1 (p-type well 2) below the auxiliary gate 4. This reversed layer extends along the auxiliary gate 4 in the Y direction of the memory array and is used as a local bit line. This permits the size of the memory cell to be reduced over the case where a diffusion layer for source or drain is formed in the p-type well 2 beforehand or where a wiring for local bit line is formed on an upper layer of a memory cell. The auxiliary gate 4 has the function of isolation between mutually adjacent memory cells. This unnecessitates an isolation region within a memory array, making it possible to further reduce the memory cell size. The control gate 12 constitutes a word line WL and, for example, 256 word lines are formed relative to one block of memory cells.

As shown in FIG. 3, the auxiliary gate 4 is formed on the gate insulating film (gate oxide film) 3 on the surface of the p-type well 2. The auxiliary gate 4 is formed of a conductor film such as, for example, an n-type polycrystalline silicon film, on which a silicon nitride film 5 is, for example, formed as an insulating film, which constitutes a cap insulating film of the auxiliary gate 4. A side wall spacer 8 made of an insulating film such as a silicon oxide film is formed on the respective side walls of the auxiliary gate 4 and the silicon nitride film 5. As stated hereinafter, the AND flash memory according to the embodiment has the side wall spacer 8 constituted of a dense silicon oxide film.

The floating gate 10 for charge storage is placed in a space region between mutually adjacent auxiliary gates 4, 4 and is formed on a silicon oxide film 9 on the surface of the p-type well 2. The silicon oxide film is a film acting as a tunnel insulating film of the memory cell. When electrons are injected into the floating gate 10 from the surface of the p-type well 2 through the silicon oxide film 9, writing of information is performed. On the other hand, when electrons are discharged into the p-type well 2 from the floating gate 10 through the silicon oxide film 9, information is erased. The floating gate 10 is insulated from the auxiliary gate 3 through the insulating film (silicon oxide film) formed on the side walls of the auxiliary gate 4 and the side wall spacer 8.

The floating gate 10 and the control gate 12 (word line WL) formed thereon are insulated from each other through an ONO film 11. The ONO film 11 is formed of two silicon oxide films and a silicon nitride film interposed therebetween. The control gate 12 (word line WL) is formed of a polycide film including, for example, an n-type polycrystalline silicon film doped with P, As or the like as a conductor film, and a high melting metal film, such as, for example, tungsten silicide (WSi), deposited thereon as a conductor film.

The floating gate 10 is formed such that the surface of the p-type well is higher than the auxiliary gate 4. This enables one to work the memory cell at high speed even if miniaturization of the memory cell is advanced. This is because an opposing area between the floating gate 10 and the control gate 12 is increased, thereby suppressing a lowering of a coupling ratio.

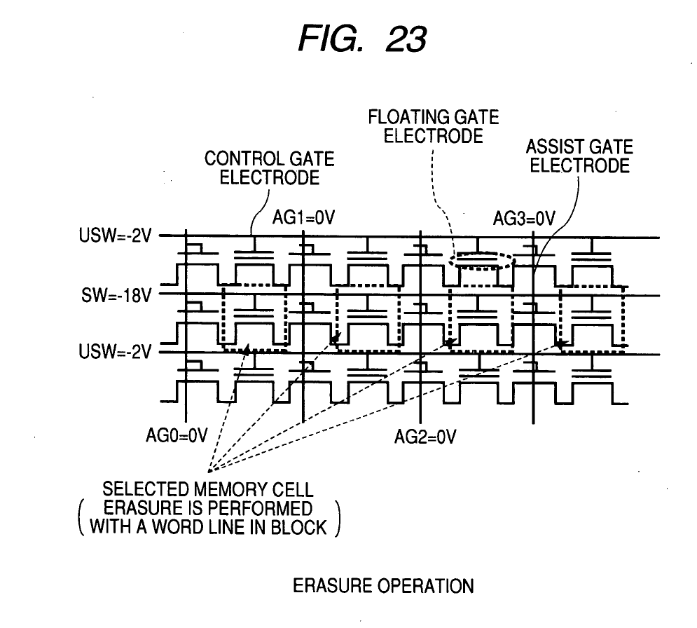

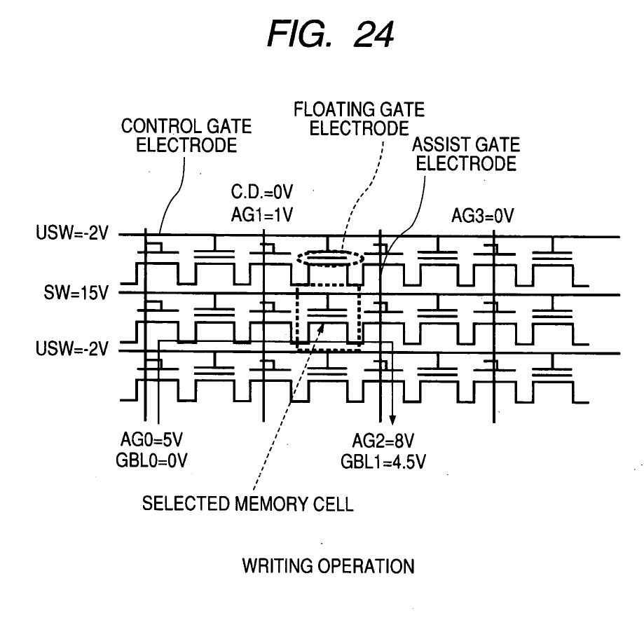

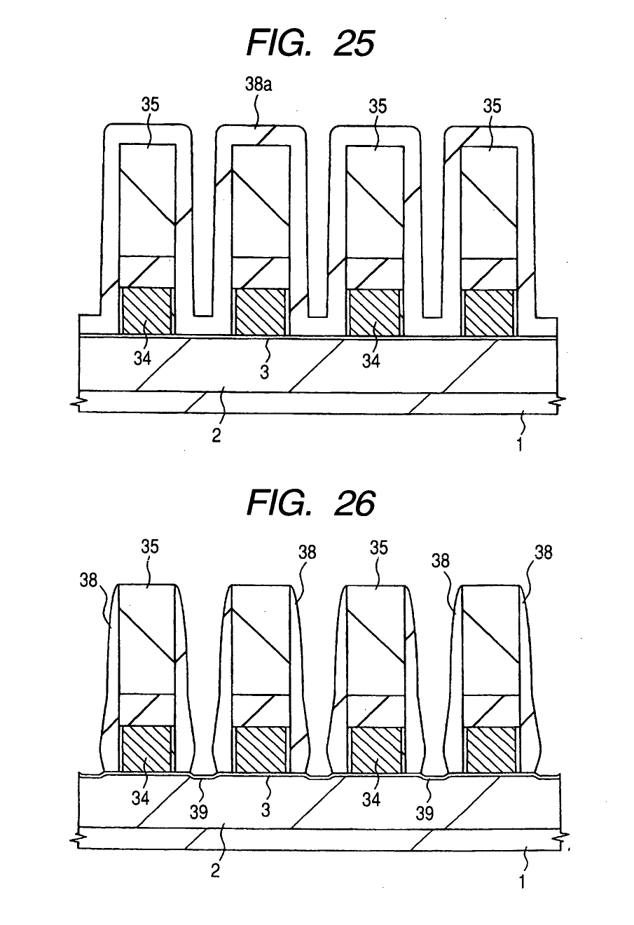

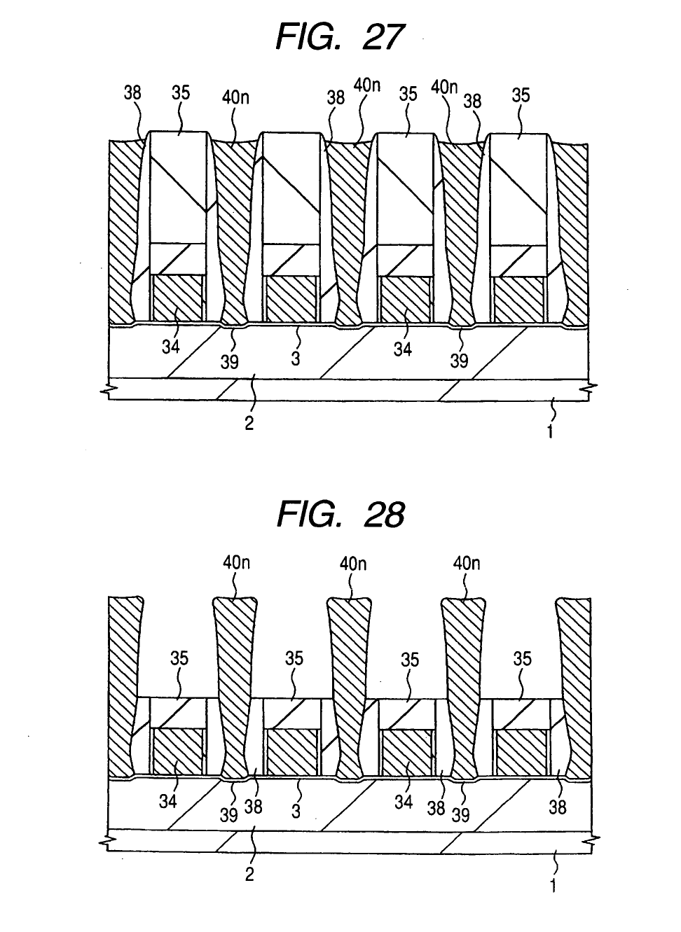

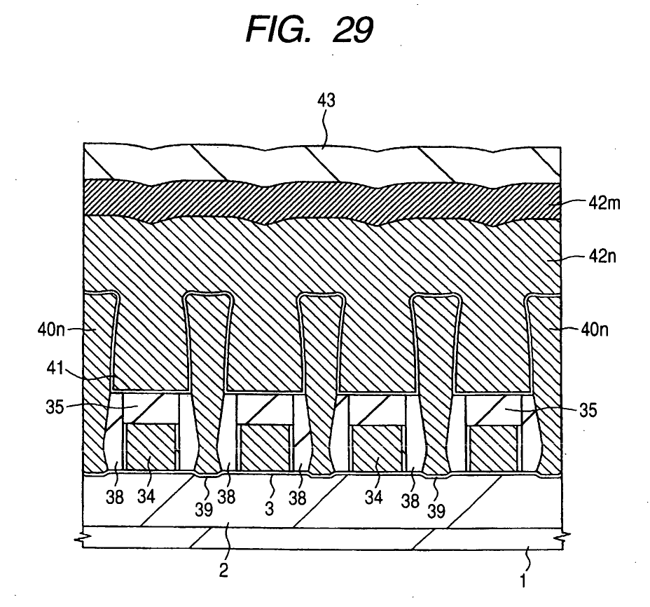

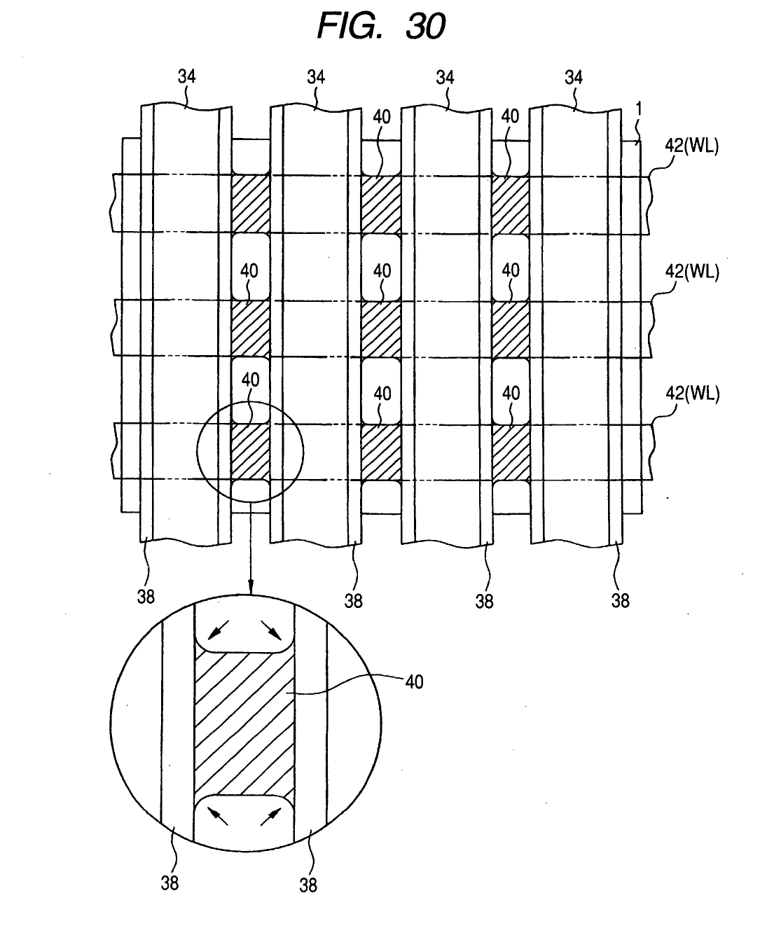

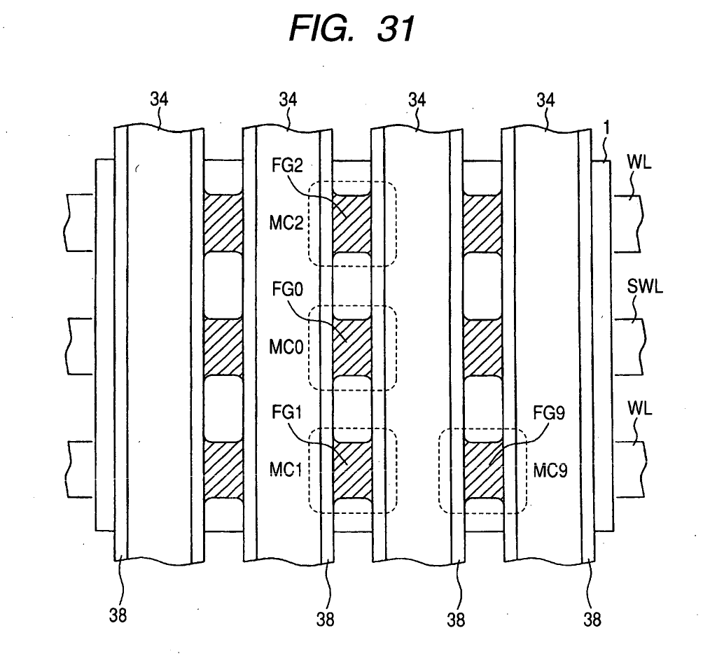

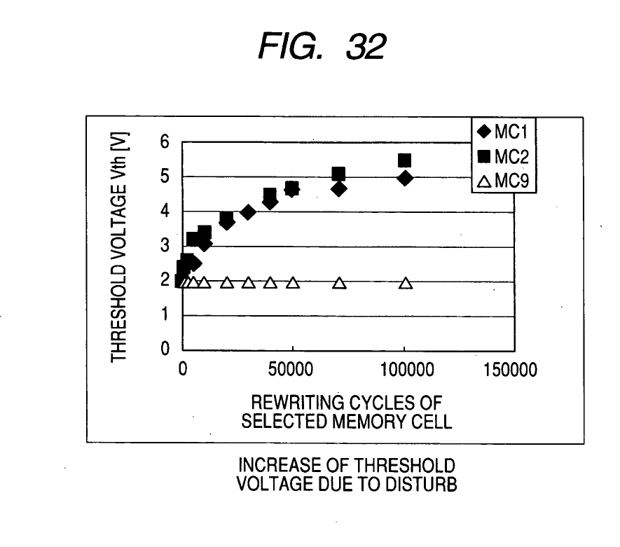

FIGS. 23 and 24 are, respectively, a circuit diagram showing voltage application conditions where information is rewritten to a given selected memory cell. The AG-AND flash memory enables information of a memory cell to be rewritten per unit word line.

For the erasure of data in a given memory cell, as shown in FIG. 23, a given erasure voltage is initially applied to a selected word line and the respective auxiliary gates AGn (n=0-3), so that electrons in the floating gate 10 are discharged against the substrate ( F-N (Fowler Nordheim)) tunnel discharge). This permits the threshold voltage of all the memory cells MC connected to the selected word line SW to be set at an erasure condition of a given value or below.

For writing data to a given memory cell, as shown in FIG. 24, 8 V is applied to a selected gate AG2 and 5 V is applied to a selected gate AG0. Simultaneously, a voltage lower than the voltages applied to the selected gates AG0 and AG2 is applied to a selected gate AG1 adjacent the selected memory cells to which writing is performed. In this condition, a reversed layer is formed on the surface of the semiconductor substrate below the selected gate AG0 and the selected gate AG2, respectively. The reversed layer below the selected gate AG2 is electrically connected with a bit line GBL1 and is applied with a potential of about 4.5 V. The reversed layer below the selected gate AG0 is electrically connected with a bit line GBL0 and is applied with a ground potential of 0 V. This permits an electric current to pass from the reversed layer at the side of the bit line GBL1 toward the reversed line at the side of the bit line GBL0. An electric field is concentrated between a channel of a selected memory cell which is to be written and a weakly reversed layer formed below an adjacent selected gate AG1. The concentration of the electric field causes hot electrons to be generated on the surface of the semiconductor substrate. The hot electrons are injected into the floating gate of the selected memory cell by the action of an electric field resulting from a high potential of the selected word line SW. When the electrons are injected into the floating gate, the selected memory cell becomes high in threshold voltage and is in a state where data is written.

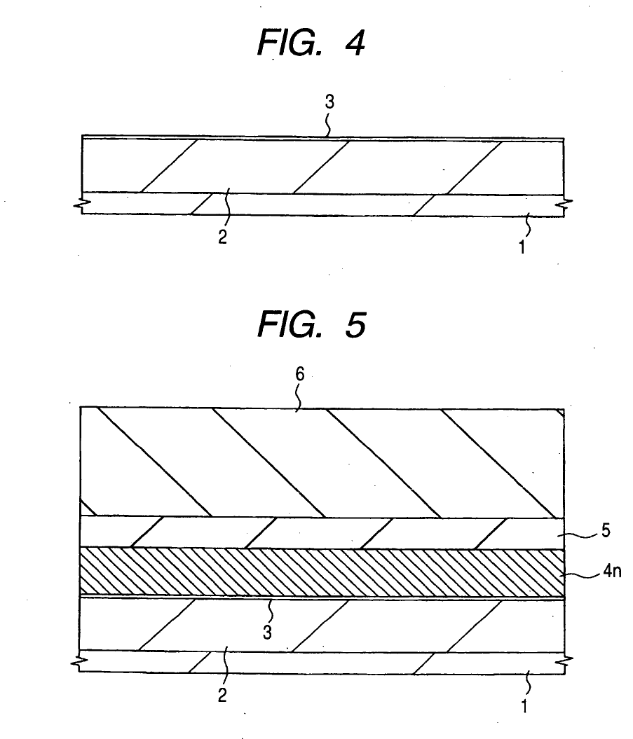

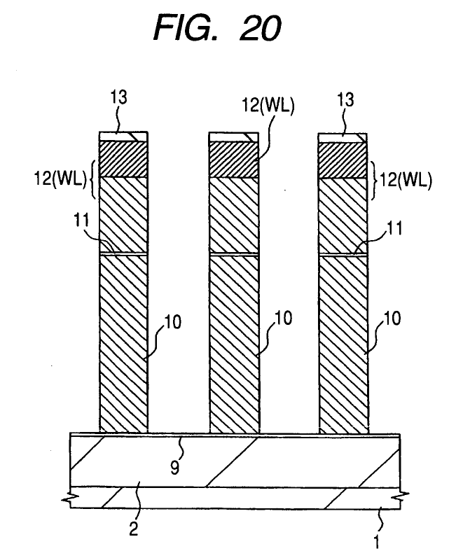

Referring to FIGS. 4 to 20, a method of manufacturing the AND flash memory according to this embodiment is illustrated in the order of steps.

Initially, as shown in FIG. 4, boron (B) is ion implanted into a semiconductor substrate (hereinafter referred to simply as substrate) made of p-type single crystal silicon having a specific resistance of about 1-10 Ω cm to form a p-type well 2. Subsequently, the substrate 1 is thermally oxidized to form a gate oxide film 3 having a thickness of about 7 to 9 nm on the surface of the p-type well 2.

Next, as shown in FIG. 5, an n-type polycrystalline silicon film 4n doped with phosphorus (P) or arsenic (As) is deposited on the gate oxide film 3 by a CVD method. Thereafter, a silicon nitride film 5 and a silicon oxide film 6 are, respectively, deposited on the n-type polycrystalline silicon film 4n as a cap insulating film. The thickness of the n-type polycrystalline silicon film is at about 70 nm. In order to adequately increase a height of a floating gate 10 formed subsequently, the thickness of the cap insulating film (silicon nitride film 5 and silicon oxide film 6) is at least made larger, preferably by two times or over, than the thickness of the n-type polycrystalline silicon film 4n. In this embodiment, the thickness of the silicon nitride film is at about 70 nm and that of the silicon oxide film is at about 250 nm. In this way, the silicon oxide film 6 should be made large in thickness and is deposited by a CVD method whose film-forming speed is high, e.g. by a normal to low pressure CVD method using a liquid source TEOS (tetraetoxysilane) as a starting material.

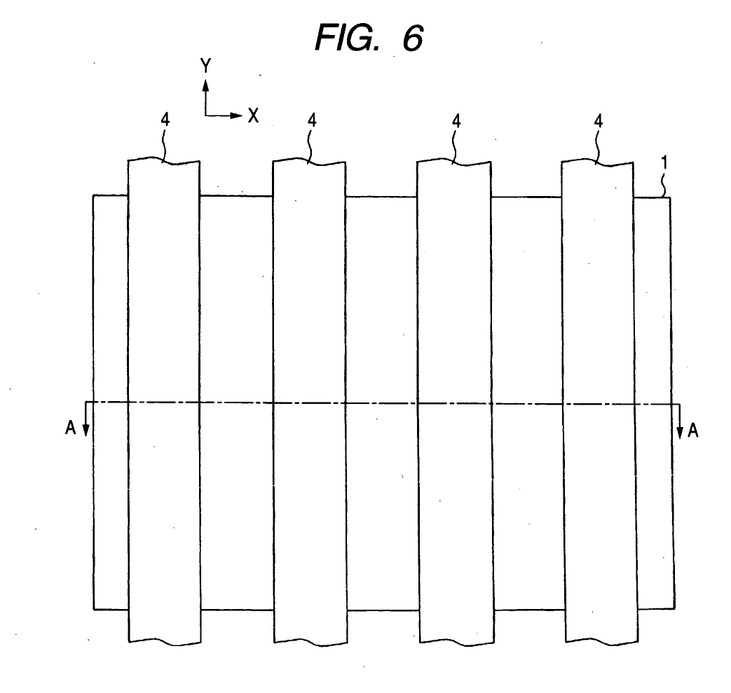

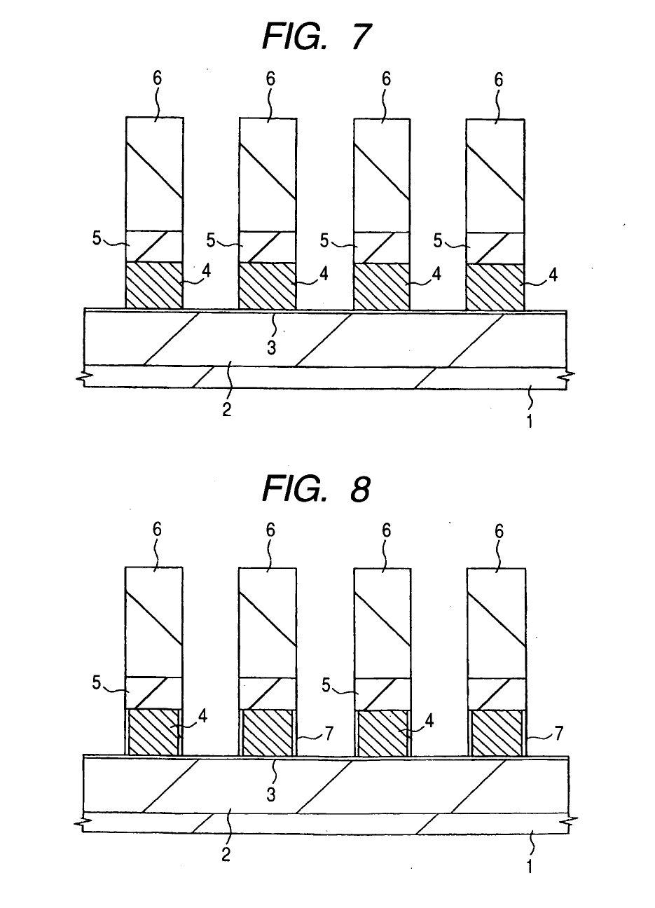

Next, as shown in FIGS. 6 and 7 (which is a section taken along line A-A of FIG. 6), the silicon oxide 6, silicon nitride film 5 and n-type polycrystalline silicon film 4n are patterned by dry etching using a photoresist film as a mask, thereby forming an auxiliary gate 4 made of the n-type polycrystalline silicon film 4n.

As shown in FIG. 8, a thin silicon oxide film 7 having a thickness of about 10 nm is formed on side walls of the thus processed auxiliary gate 4 (n-type polycrystalline silicon film 4n) by thermal oxidation treatment. The silicon oxide film on the side walls of the auxiliary gate 4 is formed to improve a withstand voltage between the auxiliary gate 4 and a floating gate 10 formed in a subsequent step. It will be noted that when the thermal oxidation is carried out, a silicon oxide film 7 is formed on the surface of the p-type well between the auxiliary gates 4, 4.

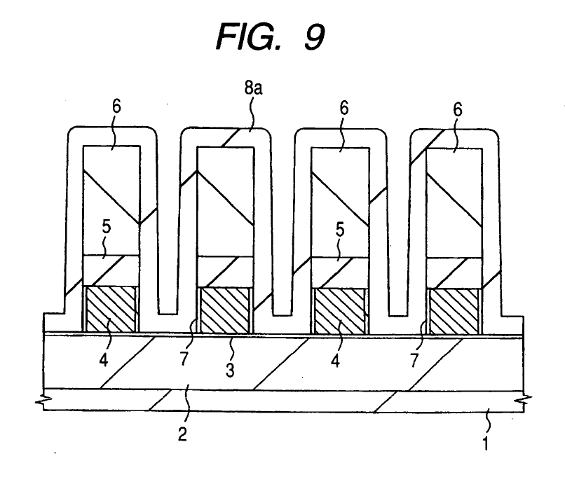

Next, as shown in FIG. 9, a silicon oxide 8a having a thickness of about 40 nm is deposited on the substrate by a CVD method. This silicon oxide film 8a is constituted of a so-called high temperature oxide film (HTO film) that is deposited by use of dichlorosilane as a starting material at a high temperature of about 800° C. so as to be more dense than the silicon oxide film 6 constituting part of the cap insulating film. Moreover, after the film formation, post-annealing is effected at a temperature not lower than the film-forming temperature.

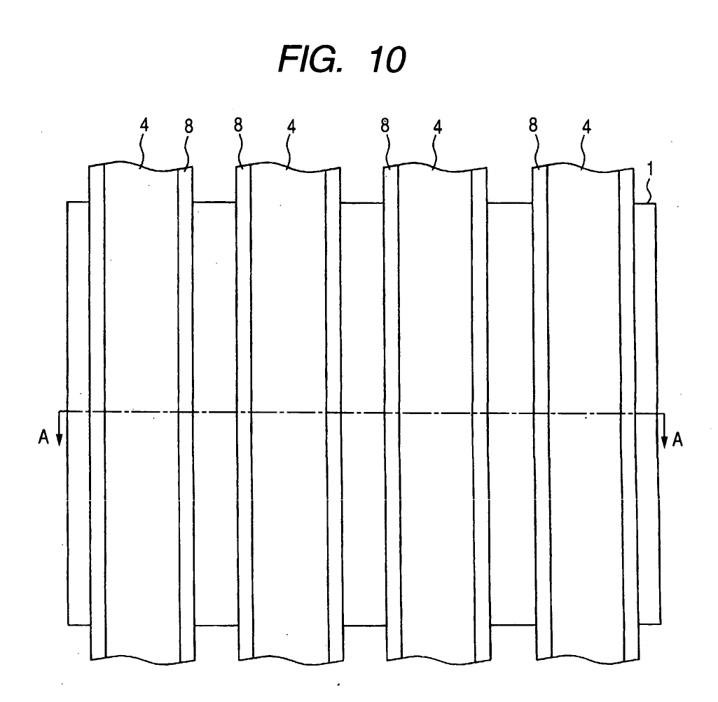

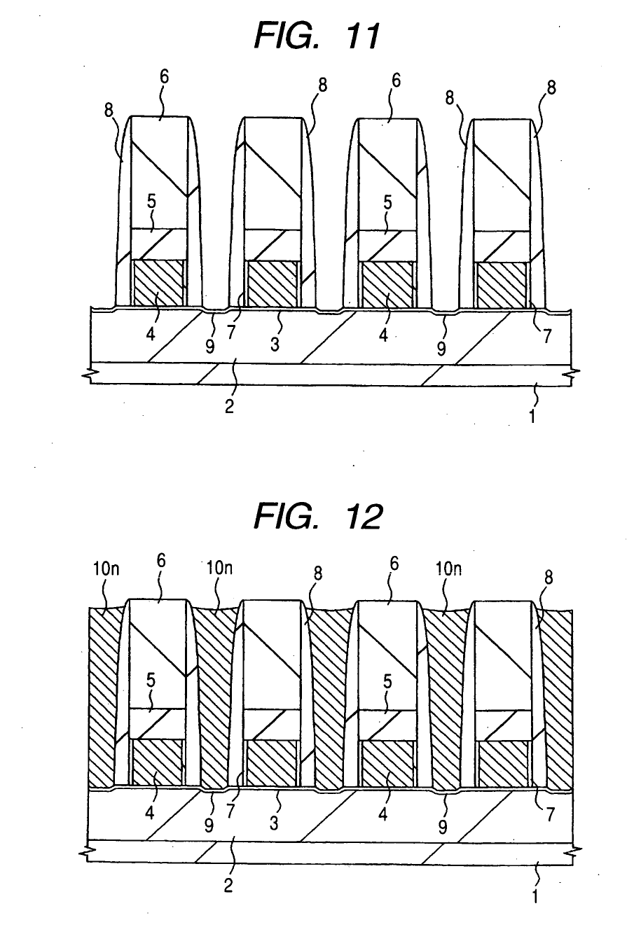

Next, as shown in FIGS. 10 and 11, the silicon oxide film 8a is anisotropically etched to form a side wall spacer 8 on the respective side walls of the auxiliary gate 4 and the cap insulating film (silicon nitride film 5 and silicon oxide film 6).

Since the silicon oxide film 8a (high temperature oxide film) constituting the side wall spacer 8 is more dense than a silicon oxide film (TEOS film) deposited by a CVD method using TEOS as a starting material, its anisotropic etching speed is smaller than with the TEOS film. Especially, in the narrow space region between the auxiliary gates 4, 4 where the side wall spacer 8 is formed, a etching rate is liable to lower remarkably owing to the microloading effect of dry etching. Taking into account a degree of denseness of elements within the plane of the substrate 1, a difference in etching rate arises between the central region and the peripheral region of the memory array. Moreover, there are slight variations in the size of the auxiliary gate 4, the thickness of the silicon oxide film 8a and the space width between the auxiliary gates 4, 4.

For these reasons, where the side wall spacer 8 is formed by anisotropic etching of the silicon oxide film 8a made of a high temperature oxide film, the thickness of the side wall spacer 8 is liable to vary. To cope with this in this embodiment, the silicon oxide film 8a is etched under conditions where the pressure in the chamber of a drying etching apparatus is lowered to 10 Pa or below, preferably about 5 Pa. This enables one to reduce the variation in thickness of the side wall spacer 8 ascribed to many factors set out above, thereby forming a forward tapered side wall spacer 8 that is free of irregularities on the surface thereof.

When the above anisotropic etching is carried out, the silicon oxide film 7 on the surface of the p-type well is etched in the space region of the auxiliary gates 4, 4, so that an etching damage layer containing carbon formed on the etching is formed on the exposed surface of the p-type well 2. Therefore, low-damage drying etching is effected to remove the etching damage layer, and wet etching is subsequently performed to clean the surface of the p-type well 2, followed by thermal treatment of the substrate 1 to form a silicon oxide film 9 having a thickness of about 7-10 nm on the surface of the p-type well 2. It will be noted that for the formation of the silicon oxide film 9, the substrate 1 maybe thermally treated in an atmosphere of nitrogen. This permits nitrogen to segregate at the interface between the silicon oxide film 9 and the p-type well 2 to improve the properties of the silicon oxide film 9 functioning as a tunnel oxide film of the memory cell, resulting in an improve charge retention characteristic.

Next, as shown in FIG. 12, a phosphorus or arsenic-doped n-type polycrystalline silicon film 10n is deposited over the substrate 1 by a CVD method, and is etched back on the surface thereof so that the etched-back surface becomes slightly lower than the surface of the silicon oxide film 6 (cap insulating film). The surface step between the n-type polycrystalline silicon film 10n and the silicon oxide film 6 should preferably be within a range of about 30 nm. The n-type polycrystalline silicon film 10n is a conductor film serving for a floating gate 10 in a subsequent step.

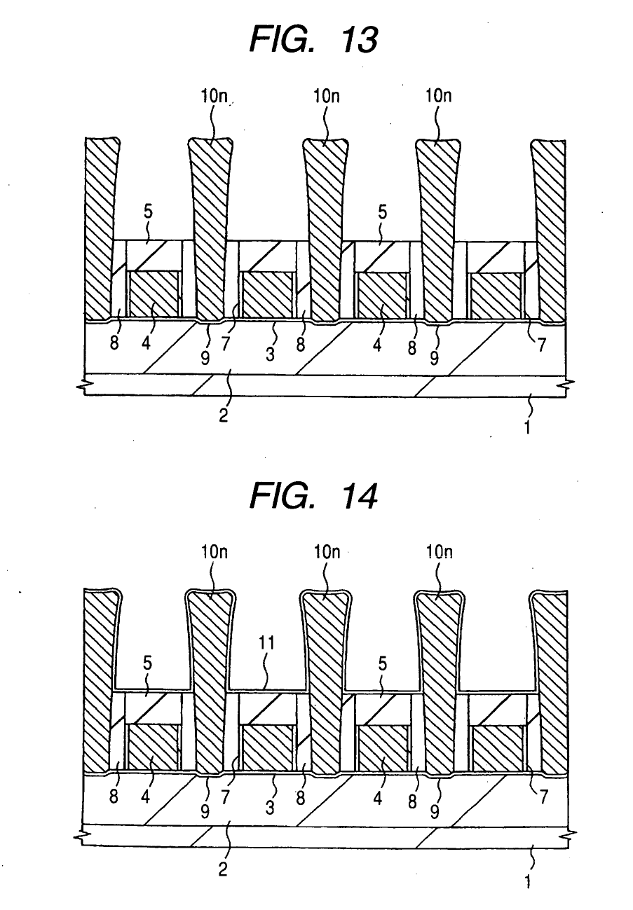

Next, as shown in FIG. 13, the silicon oxide film, which is a part of the cap insulating film, is removed by dry etching. This dry etching makes use of the silicon nitride film 5, which is a residue of the cap insulating film, as an etching stopper. When the silicon oxide film is dry etched, the side wall spacer 8 above the upper surface of the exposed silicon nitride film 5 is also removed so that the upper surface of the silicon nitride film 5 and the upper surface of the side wall spacer 8 are substantially at the same level. According to the steps thus far described, the striped n-type polycrystalline silicon film 10n that is higher than the auxiliary gate 4 and extends in the same direction is formed self-alignedly relative to the auxiliary gate 4 and the side wall spacer 8. Since the n-type polycrystalline silicon film 10n is deposited on the forward tapered side wall spacer 8 whose surface is irregularity-free, the n-type polycrystalline silicon film 10n is so shaped as to have no surface irregularities.

Next, as shown in FIG. 14, an ONO film 11 is formed over the substrate 1. The ONO film 11 is constituted of a three-layered insulating film (silicon oxide film, silicon nitride film and silicon oxide film) formed according to a CVD method. The two silicon oxide films sandwiching the silicon nitride film therebetween may be formed by a thermal oxidation method in place of the CVD method.

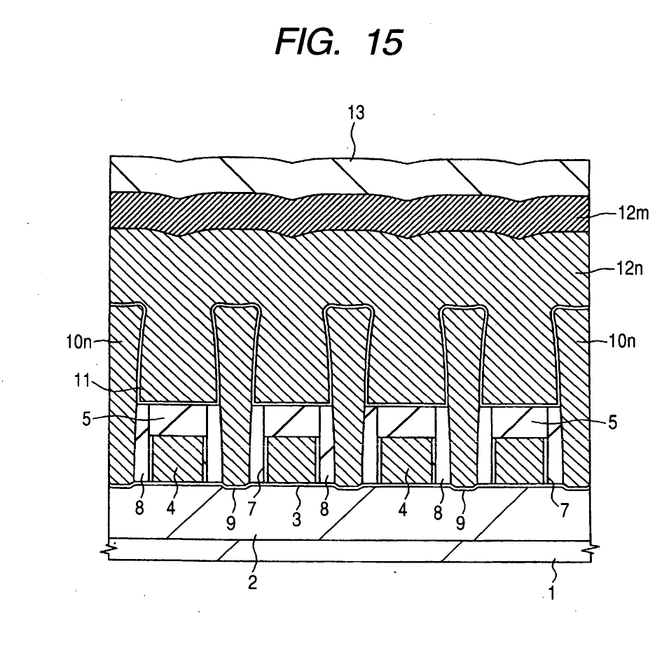

Next, as shown in FIG. 15, a phosphorus or arsenic-doped n-type polycrystalline silicon film 12n, a tungsten silicide film 12m and a silicon oxide film 13 are successively deposited on the ONO film 11 by use of a CVD method. The thickness of the n-type polycrystalline silicon film 12n above the n-type polycrystalline silicon film ion is at about 80 nm, and the thicknesses of the tungsten silicide film 12m and the silicon oxide film 13 are, respectively, at about 150 nm.

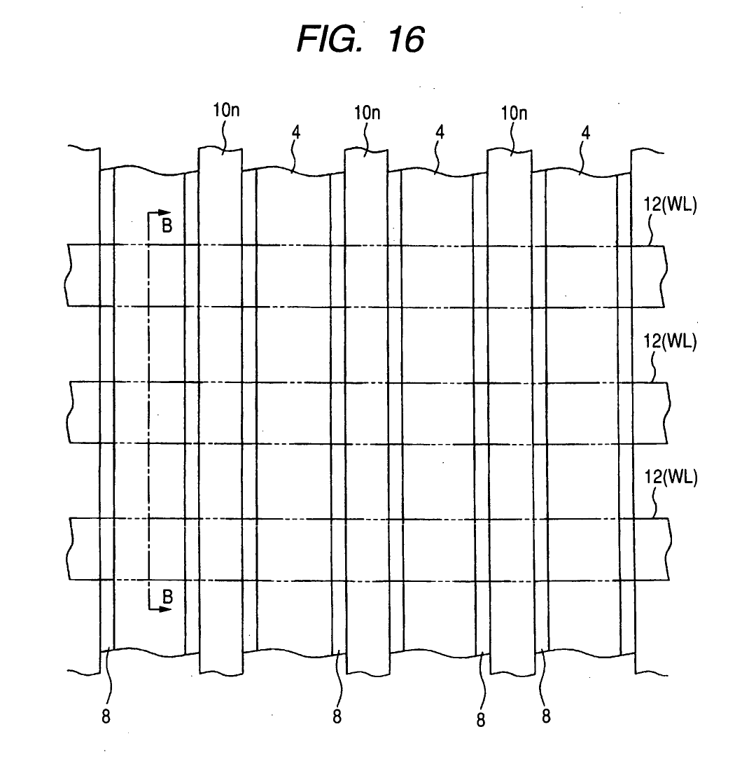

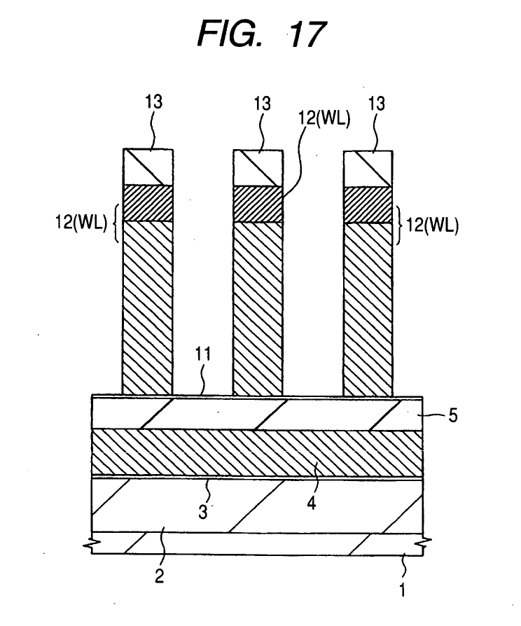

As shown in FIGS. 16 and 17 (a sectional view taken along line B-B of FIG. 16), the silicon oxide film 13 is patterned by dry etching using a photoresist film as a mask. Subsequently, after removal of the photoresist film, the tungsten silicide film 12m and the n-type polycrystalline silicon film 12n are, respectively, patterned using the silicon oxide film 13 as a mask. According to the steps thus far described, a control gate 12 made of the tungsten silicide film 12m and the n-type polycrystalline silicon film 12n (word line WL) is formed.

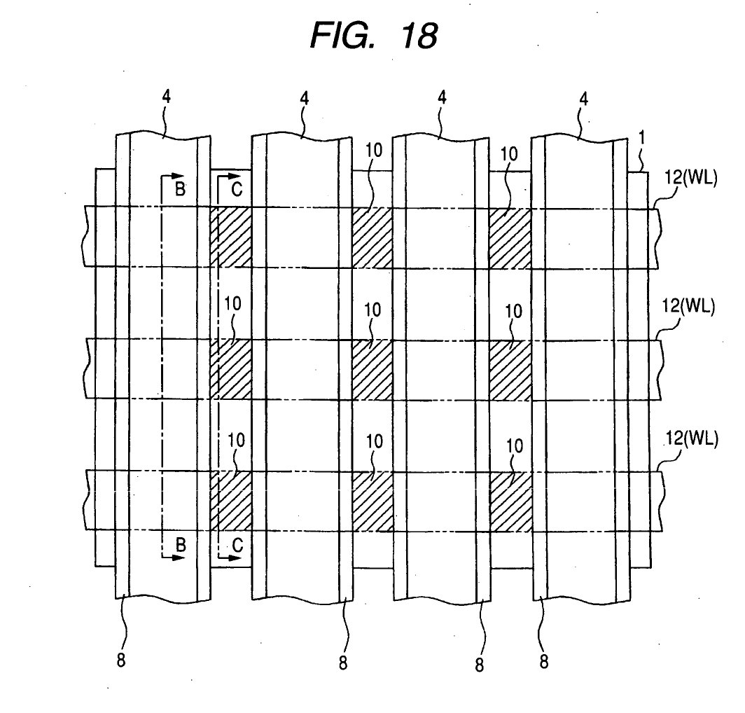

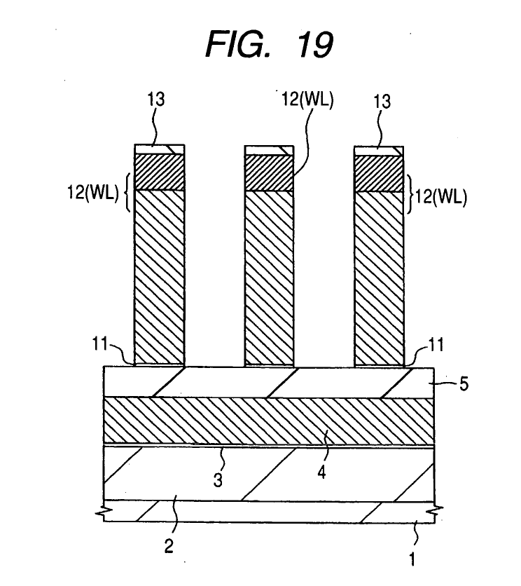

Next, as shown in FIGS. 18, 19 (a sectional view taken along line B-B of FIG. 18) and 20 (a sectional view taken along line C-C of FIG. 18), the ONO film 11 and the n-type polycrystalline silicon film 10n in the space region between the control gates 12, 12 is dry etched using the silicon oxide film 13 covering the control gate 12 (word line WL) as a mask. Thereafter, in order to remove the remaining film of the n-type polycrystalline silicon film 10n that is not removed by the dry etching, a wet etching treatment using a hot APM (ammonia+hydrogen peroxide) cleaning solution or fluorine nitrate. More particularly, the patterning of the word line WL and the floating age 10 is carried out by use of dry etching and wet etching. According to the foregoing steps, the- striped n-type polycrystalline silicon film ion extending in the same direction as the auxiliary gate 4 is isolated on a cell-to-cell basis, and the floating gate 10 is formed self-alignedly relative to the control gate 12 (word line WL).

Thereafter, thermal oxidation by a high temperature rapid heating treatment using a gas containing molecular oxygen (O₂) is carried out on the main surface of the semiconductor substrate. According to this thermal oxidation treatment, the exposed semiconductor substrate, side surfaces of the floating gate 10 and side surfaces of the control gate 12 are, respectively, oxidized, and an oxide film having about several nanometers is formed thereon (not shown). The main purposes of the thermal oxidation treatment is to suppress the concentration of an electric field at the end of the floating gate 10. In addition, the purpose is to completely remove the remaining film of the n-type polycrystalline silicon film 10n, which has not been removed by the drying etching and wet etching and is slightly left.

The thermal oxidation treatment may be effected by an ISSG (in-situ steam generation) oxidation process. The ISSG oxidation process is one wherein hydrogen and oxygen are directly introduced into a thermal treating chamber reduced in pressure so as to carry out a radical oxidation reaction in an atmosphere of about 1000° C.

As stated hereinabove, according to the manufacturing method of this embodiment, the side wall spacer 8 has no irregularity on the surface thereof and is forward tapered. Thus, no problem is involved in that when the n-type polycrystalline silicon film 10n is dry etched to form the floating gate 10, the n-type polycrystalline silicon film 10n is left non-etched at a portion thereof where shaded with the side wall spacer 8 as in prior art. More particularly, according to the manufacturing method of this embodiment, when the n-type polycrystalline silicon film 10n is dried etched to form the floating gate 10, a short-circuiting failure, which is caused by a shape failure of the side wall spacer 8, can be reliably prevented without isolation between the floating gates 10, 10.

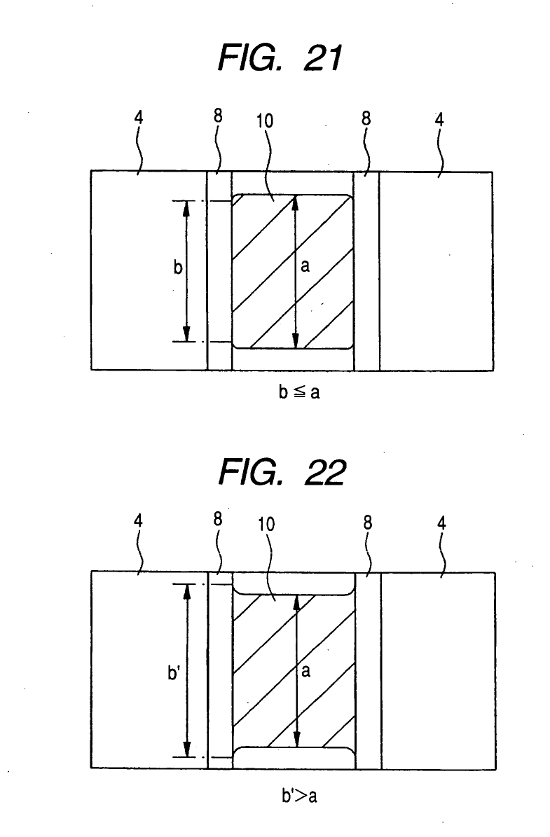

Further, as stated hereinbefore, according to the manufacturing method of this embodiment, the deposition of the n-type polycrystalline silicon film 10n on the forward tapered side wall spacer 8 having no surface irregularity results in an irregularity-free surface shape of the n-type polycrystalline silicon film 10n. This leads to the fact that when wet etching treatment with an APM solution is carried out after the formation of the floating gate 10 by dry etching of the n-type polycrystalline silicon film 10n, a remaining film extending as a whisker from the four corners of the floating gate 10 and the skin film on the side surfaces of the side wall spacer 8 can be well removed. Accordingly, as shown in FIG. 21, the planar shape of the floating gate 10 is rectangular, i.e. a length b of a portion contacting with the side wall spacer 8 (i.e. a length along a direction of extension of the auxiliary gate 4) is equal to or smaller than a length a of a central portion (b≦a).

On the other hand, FIG. 22 shows a planar shape of the floating gate 10 that is obtainable in case where the side wall spacer formed at the side walls of the auxiliary gate is constituted of a TEOS film. As stated hereinbefore, when a silicon oxide film deposited by a CVD method using TEOS as a starting material is anisotropically etched under relatively high pressure etching conditions, the processed shape of the side wall spacer is liable to become irregular. This causes the floating gate 10, which is formed self-alignedly relative to the auxiliary gate and the side wall spacer, to be so deformed that the four corners thereof becomes sharp as if a horn projects from each corner. More particularly, the planar shape of the floating gate 10 is such that a length of a portion contacting with the side wall spacer (a length of a direction of extension of the auxiliary gate) b′ is larger than a length a at the central portion (b′>a). When the floating gate is so shaped as mentioned above, an electric field is concentrated at the four corners of the floating gate 10 upon erasure and is discharged against the substrate in a condition where electrons have a high energy, so that a secondary electron generates in the substrate. The injection of the secondary electron into the floating gate adjacent memory cells, there occurs a disturb phenomenon where a threshold voltage of the adjacent memory cells undesirably increases. On the other hand, the floating gate 10 of this embodiment does not have such a shape that the four corners are sharpened as if a horn projects from each corner, so that the occurrence of the disturb phenomenon can be suppressed.

The invention has been particularly illustrated based on the embodiments thereof, which should not be construed as limiting the invention thereof. As a matter of course, many variations or alterations may be possible without departing from the spirit of the invention.

For instance, multivalued information may be memorized in the memory cell MC. The multivalued memorization is carried by making a writing voltage of a selected word line SW constant and varying a writing time to vary a quantity of electrons injected into the floating gate 4, so that there can be formed memory cells MS having several kinds of threshold levels. More specifically, four or more levels of “00”/“01”/“10”/“11” can be memorized. In this way, one memory cell MC serves as two memory cells, thus realizing miniaturization of a flash memory.

In the above embodiments, the application to an AG-AND flash memory having a floating gate higher than an auxiliary gate has been described. The invention is not limited only to such an application. More particularly, the invention can be applied to ordinary AG-AND flash memories of the type wherein a first conductor film is filled in a space region of an auxiliary gate whose side walls are formed with a side wall spacer, and the first conductor film is patterned upon pattering of a second conductor film for control gate thereby forming a floating gate.

The invention is effective for application to a semiconductor device wherein a flash memory is constituted of a floating gate electrode for charge storage, a control gate electrode and an auxiliary gate electrode.

1. A method of manufacturing a semiconductor device, comprising the steps of:
(a) forming a first conductor film over a main surface of a semiconductor substrate and subsequently forming, over the first conductor film, a cap insulating film having a thickness larger than the first conductor film;
(b) patterning the cap insulating film and the first conductor film to form a first conductor piece which is covered with the cap insulating film over a top thereof; and
(c) forming a high temperature oxide over a main surface of the semiconductor substrate by use of a CVD method using dichlorosilane as a starting material, thereafter anisotropically etching the high temperature oxide film to form a side wall spacer, made of the high temperature oxide film, to the respective side walls of the first conductor piece and the cap insulating film.

2. The method according to claim 1, wherein the cap insulating film has a thickness larger by two times or over than the first conductor film.

3. The method according to claim 1, wherein the high temperature oxide film has a denseness greater than the cap insulating film.

4. The method according to claim 1, wherein the anisotropic etching of the high temperature oxide film is effected under pressure conditions of not higher than 10 Pa.

5. The method according to claim 4, wherein the pressure conditions are not higher than 5 Pa.

6. A method of manufacturing a semiconductor device, comprising the steps of:
(a) forming a first conductor film over a main surface of a semiconductor substrate and subsequently forming, over the first conductor film, a cap insulating film that is formed of a multilayered film of a first insulating film and a second insulating film and has a thickness larger than the first conductor film;
(b) patterning the cap insulating film and the first conductor film to form a first conductor piece which is covered with the cap insulating film over a top thereof; and
(c) forming a high temperature oxide over a main surface of the semiconductor substrate by use of a CVD method using dichlorosilane as a starting material, thereafter anisotropically etching the high temperature oxide film to form a side wall spacer, made of the high temperature oxide film, to the respective side walls of the first conductor piece and the cap insulating film.

7. A method of manufacturing a semiconductor device, comprising the steps of:
(a) forming a first conductor film over a main surface of a semiconductor substrate and subsequently forming, over the first conductor film, a cap insulating film having a thickness larger than the first conductor film;
(b) patterning the cap insulating film and the first conductor film to form a plurality of first conductor pieces which are covered with the cap insulating film over a top thereof and extend in a first direction at a given space therebetween; and
(c) forming a high temperature oxide over a main surface of the semiconductor substrate by use of a CVD method using dichlorosilane as a starting material, thereafter anisotropically etching the high temperature oxide film to form a side wall spacer, made of the high temperature oxide film, to the respective side walls of the plurality of first conductor piece and the cap insulating film;
(d) cleaning the main surface of the semiconductor substrate, thereafter forming a silicon oxide film at space regions of the first conductor pieces by high temperature thermal oxidation treatment;
(e) forming a second conductor film over the main surface of the semiconductor substrate to fill the second conductor in the respective space regions of the first conductor pieces covered with the cap insulating film;
(f) etching back the second conductor film by anisotropic etching to such an extent that the cap insulating film is exposed and the second conductor film is left on the space regions of the first conductor pieces;
(g) after the step (f), forming a first insulating film over the main surface of the semiconductor substrate and forming a third conductor film over the fist insulating film; and
(h) patterning the third conductor film, the first insulating film and the second conductor film to form a plurality of third conductor pieces which are each made of the third conductor film and extend in a second direction intersecting with the first direction at a given space therebetween, and forming a second conductor piece, made of the second conductor film, at a lower region of individual third conductor pieces.

8. The method according to claim 7, wherein the high temperature oxide film has a denseness greater than the cap insulating film.

9. The method according to claim 7, wherein the anisotropic etching of the high temperature oxide film is effected under pressure conditions of not higher than 10 Pa.

10. The method according to claim 9, wherein the pressure conditions are not higher than 5 Pa.

11. The method according to claim 7, wherein the patterning of the second conductor film in the step (h) is carried out by a combination of dry etching and wet etching using fluorine nitrate or an APM cleaning solution.

12. The method according to claim 7, further comprising, after the step (h), forming a silicon oxide film over a side surface of the patterned second conductor film according to a high temperature rapid heating thermal oxidation method.

13. The method according to claim 7, wherein a planar dimension of the second conductor piece along the first direction is such that a length at a central portion is larger than a length of a region contacting with the side wall spacer.

14. The method according to claim 7, wherein the first conductor piece serves as an auxiliary gate electrode of a nonvolatile memory, the second conductor piece serves as floating gate electrode for charge storage of the nonvolatile memory, and the third conductor piece serves as a control gate electrode of the nonvolatile memory.

15. A method of manufacturing a semiconductor device, comprising the steps of:
(a) successively forming a first conductor film, a first insulating film and a second conductor film over a main surface of a semiconductor substrate;
(b) patterning the second conductor film, the first insulating film and the first conductor film into given shapes by dry etching; and
(c) after the step (b), wet etching the second conductor film and the first conductor film.

16. The method according to claim 15, wherein the wet etching is carried out by use of fluorine nitrate or an APM cleaning solution.

17. The method according to claim 15, wherein an amount of the first conductor film being etched in a direction parallel to the main surface of the semiconductor substrate is greater than an amount of the second conductor film being etched in the direction.

18. The method according to claim 17, wherein the wet etching is carried out by use of the APM cleaning solution.

19. The method according to claim 15, further comprising, prior to the step (a), the steps of:
(d) forming a third conductor film over the main surface of the semiconductor substrate and forming a cap insulating film on top of the third conductor film;
(e) patterning the cap insulating film and the third conductor film to form a conductor piece covered with the cap insulating film on the top thereof; and
(f) forming a second insulating film over the semiconductor substrate, thereafter anisotropically etching the second insulating film to form a side wall spacer to the respective side walls of the conductor piece and the cap insulating film.

20. The method according to claim 19, wherein in the step (b), when the second conductor film, the first insulating film and the first conductor film are patterned into desired shapes, the conductor piece is free of patterning.

21. The method according to claim 19, wherein the first conductor film serves as a floating gate electrode for charge storage of a nonvolatile memory, the second conductor film serves as a control gate electrode of the nonvolatile memory, and the conductor piece serves as an auxiliary gate electrode of the nonvolatile memory.

22. The method according to claim 19, wherein the second insulating film is formed by use of a CVD method using dichlorosilane as a starting material.

23. The method according to claim 19, further comprising, after the step (c), a step of:
(g) forming a silicon oxide film over side surfaces of the patterned first conductor film.

24. (canceled)

25. (canceled)
